(19) United States
(12) Patent Application Publication
(10) Pub. No.: US 2024/0395686 A1
(43) Pub. Date: Nov. 28, 2024

(54) Package Redistribution Layer Structures for Stress Mitigation and Alignment Tolerance

(71) Applicant: Apple Inc., Cupertino, CA (US)

(72) Inventors: Wei Chen, San Jose, CA (US); Jie-Hua Zhao, Cupertino, CA (US); Jun Zhai, Cupertino, CA (US); Kunzhong Hu, Cupertino, CA (US); Arun Sasi, Kirchheim unter Teck (DE); Balaji Nandhivaram Muthuraman, Reutlingen (DE); Zezhou Liu, San Jose, CA (US)

(21) Appl. No.: 18/324,612

(22) Filed: May 26, 2023

(51) Int. Cl. H01L 23/498; H01L 23/00; H01L 23/538

(52) U.S. Cl. CPC H01L 23/49838; H01L 23/5386; H01L 24/08; H01L 23/49822; H01L 23/49894; H01L 23/5383; H01L 24/16; H01L 2224/08121; H01L 2224/08123; H01L 2224/08225; H01L 2224/16227

(57) ABSTRACT

Electronic packages and electronic systems are described in which a package redistribution layer of the electronic package includes structural features such a via line connections to reduce stress concentration, particularly when the package redistribution layer is formed of organic dielectric materials.

### BACKGROUND

### Field

Embodiments described herein relate to electronic packaging, and more particularly to package routing layers.

### Background Information

Wafer level packaging (WLP) solutions are widely adopted in electronic packaging to accomplish various goals such as shrinking package size and height, and to reduce assembly cost. One such technology is the embedded wafer level ball grid array (eWLB) package technology in which dies are re-constituted on a carrier wafer. Such a technology can create a bigger die area, and hence higher pin count and low profile, and also allow the integration of multiple dies within the same package. Such an assembly process includes placement of an array of dies on a temporary carrier, overmolding, formation of a package redistribution layer over the array of dies, and singulation of individual packages that can contain one or more dies.

### SUMMARY

Electronic packages and systems are described to mitigate shear and peeling stress within the package redistribution layer (RDL), and in particular when formed of comparatively soft dielectric layers deposited using techniques such as spin coating and lamination. In an embodiment an electronic package structure includes an electronic component with one or more contact terminals and a package RDL on the electronic component. The package RDL may include multiple wiring layers and a via line that connects a first wiring layer of the plurality of wiring layer to a contact terminal of the electronic component and/or to another wiring layer of the plurality of wiring layers. The via line in accordance with embodiments may be characterized by a line width and a longitudinal line length that is greater than the line width. Metal wiring traces and vias of the package RDLs can additionally or alternatively be arranged in cantilever, U-turn, or symmetrical arrangements to mitigate shear and peeling stress. The electronic packages in accordance with embodiments may be further mounted onto a module substrate for integration into an electronic system.

### BRIEF DESCRIPTION OF THE DRAWINGS

FIG. 1 is a schematic cross-sectional side view illustration of an electronic system including an electronic package mounted on a module substrate in accordance with an embodiment.

FIG. 2 is a schematic cross-sectional side view illustration of package RDL a U-turn routing configuration and via line connection in accordance with an embodiment.

FIG. 3A is a schematic bottom-top view illustration of a package RDL via and wiring layer arrangement aligned with an electronic component terminal in accordance with an embodiment.

FIG. 3B is a schematic bottom-top view illustration of a package RDL via line and wiring layer arrangement aligned with an electronic component terminal in accordance with an embodiment.

FIG. 4A is a schematic bottom-top view illustration of a package RDL via and wiring layer arrangement mis-aligned with an electronic component terminal in accordance with an embodiment.

FIG. 4B is a schematic bottom-top view illustration of a package RDL via line and wiring layer arrangement mis-aligned with an electronic component terminal in accordance with an embodiment.

FIG. 5 is a schematic cross-sectional side view illustration of package redistribution layer including a U-turn routing configuration and via line connection in accordance with an embodiment.

FIG. 6 is a schematic cross-sectional side view illustration of package RDL including a cantilever routing configuration and via line connection in accordance with an embodiment.

FIG. 7A is a schematic cross-sectional side view illustration of package RDL including a via line connection and wiring bridges in accordance with an embodiment.

FIG. 7B is a schematic bottom-top view illustration of a package RDL including a via line connection and wiring bridges in accordance with an embodiment.

FIG. 7C is a schematic perspective view illustration of a package RDL including a via line connection and wiring bridges in accordance with an embodiment.

FIG. 8A is a schematic cross-sectional side view illustration of package RDL including a straight via line bridge between two terminals of an electronic component in accordance with an embodiment.

FIG. 8B is a schematic bottom-top view illustration of package RDL including a straight via line bridge between two terminals of an electronic component in accordance with an embodiment.

FIG. 9A is a schematic cross-sectional side view illustration of package RDL including a straight via line bridge between multiple terminals of an electronic component in accordance with an embodiment.

FIG. 9B is a schematic bottom-top view illustration of package RDL including a straight via line bridge between multiple terminals of an electronic component in accordance with an embodiment.

FIG. 10A is a schematic cross-sectional side view illustration of package RDL including a jogged via line bridge between two terminals of an electronic component in accordance with an embodiment.

FIG. 10B is a schematic bottom-top view illustration of package RDL including a jogged via line bridge between two terminals of an electronic component in accordance with an embodiment.

FIG. 11A is a schematic cross-sectional side view illustration of package RDL including jogged via line bridge between multiple terminals of an electronic component in accordance with an embodiment.

FIG. 11B is a schematic bottom-top view illustration of package RDL including a jogged via line bridge between multiple terminals of an electronic component in accordance with an embodiment.

FIG. 12 is a schematic cross-sectional side view illustration of package RDL including a symmetrical routing configuration and via line connection in accordance with an embodiment.

FIG. 13A is a schematic bottom-top view illustration of a package RDL including a symmetrical routing configuration and via connection in accordance with an embodiment.

FIG. 13B is a schematic bottom-top view illustration of a package RDL including a symmetrical routing configuration and via line connection in accordance with an embodiment.

FIG. 14 is a schematic cross-sectional side view illustration of a package RDL including an offset symmetrical routing configuration in accordance with an embodiment.

FIG. 15A is a schematic bottom-top view illustration of a package RDL including an offset topmost via connection in accordance with an embodiment.

FIG. 15B is a schematic bottom-top view illustration of a package RDL including an aligned topmost via connection in accordance with an embodiment.

FIG. 16 is a schematic cross-sectional side view illustration of a package RDL including a symmetrical routing configuration and multiple via connections in accordance with an embodiment.

FIG. 17A is a schematic bottom-top view illustration of a package RDL including a symmetrical routing configuration and multiple top via connections in accordance with an embodiment.

FIG. 17B is a schematic bottom-top view illustration of a package RDL including a symmetrical routing configuration and multiple lower metal layer via connections in accordance with an embodiment.

FIG. 18 is a schematic cross-sectional side view illustration of a package RDL including a symmetrical routing configuration and multiple mid-level via connections and a via line connection in accordance with an embodiment.

FIG. 19A is a schematic bottom-top view illustration of a package RDL including a symmetrical routing configuration and multiple mid-level via connections in accordance with an embodiment.

FIG. 19B is a schematic bottom-top view illustration of a package RDL including a symmetrical routing configuration and a line via connection in accordance with an embodiment.

### DETAILED DESCRIPTION

Embodiments describe electronic systems, electronic packages, and methods of manufacture. In an embodiment an electronic system includes a module substrate and an electronic package mounted on the module substrate. The electronic package in accordance with embodiments can include an electronic component and a package redistribution layer (RDL) on the electronic component. Specifically, the package RDL may be connected to contact terminals of the electronic component and include a plurality of wiring layers. In accordance with embodiments, the package RDL includes a via line connection between adjacent wiring layers or between a top wiring layer of the package RDL and a contact terminal of the electronic component. The via line may be distinguishable from a traditional via in that the via line may be characterized by a line width and a longitudinal line length that is greater than the line width as opposed to a via diameter.

In one aspect it has been observed that shear and peeling stress occurs in package RDLs when a package is subjected to thermal loading. In particular, it has been observed that package RDL vias closest to the electronic component on which the package RDL is formed can be particularly vulnerable to failure (e.g. crack, fatigue) due to smaller dimensions by design. For example, vias closest the electronic component can have smaller dimensions compared to vias closer the package solder bumps due to maintaining alignment tolerances within the component terminal footprint. In accordance with embodiments, strain loading can be reduced by changing dimensions of the package RDL vias. Via line connections for example can be integrated to mitigate stress concentration. Staggering and U-turn designs within the package RDL can also be included to further reduce stress depending upon the application and loading conditions, particularly with advanced technologies with smaller pitch. In an embodiment, a symmetrical via and wiring trace design within the package RDL can be included to reduce stress.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

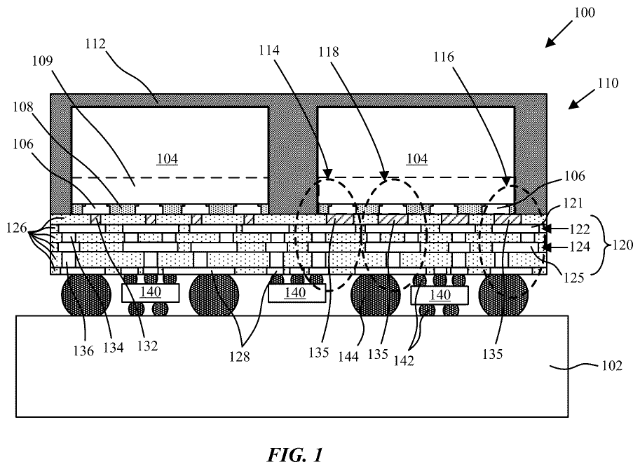

Referring now to FIG. 1 a schematic cross-sectional side view illustration is provided of an electronic system 100 including an electronic package 110 mounted on a module substrate 102. The module substrate 102 may be a variety of substrates including traditional substrates such as ABF (Ajinomoto Build-up Film), metal or metal core substrates, silicon core substrates, ceramics, polymers, FR-2 (a phenolic paper impregnated with resin), FR-4 (a woven fiberglass impregnate with resin), etc. The module substrate 102 may be rigid or flexible. The module substrate 102 may be an inorganic or organic interposer, or a lower electronic package.

The electronic package 110 can include one or more electronic components 104 optionally embedded in a molding compound layer 112. Each electronic component 104 may include a back-end-of-the-line (BEOL) build-up structure 109 culminating with a passivation layer 108 and contact terminals 106. Components 104 may be the same or different. The component(s) may be a variety of suitable components such as, but not limited to, a graphics processing unit (GPU), central processing unit (CPU), artificial intelligence (AI), machine learning logic, radio-frequency (RF) baseband processor, radio-frequency (RF) antenna, signal processors, power management integrated circuit (PMIC), cache, logic, memory, photonics, biochips, silicon interconnect and any combinations thereof.

The package RDL 120 in accordance with embodiments may be formed of organic or inorganic materials. For example, an organic package RDL 120 can include a plurality of metal wiring layers 122, 124 including metal wiring traces 121, 125 and a plurality of polymer dielectric layers 126. While only two metal wiring layers are illustrated this is exemplary and embodiments may have more or less metal wiring layers. The metal wiring layers 122, 124 can be connected by intermediate vias 134 or via lines. Package RDL 120 may be formed using a layer-by-layer thin film processing sequence, such as spin coating or lamination of the polymer dielectric layers 126, followed by patterning and deposition of the metal wiring layers 122, 124 and vias. Package RDL 120 may additionally include package terminals 128 (e.g. landing pads), which may receive solder bumps 144 for mounting onto module substrate 102, and/or micro bumps 142 for mounting of chiplets 140. For example, chiplets 140 may include various passive components, such as capacitors, or active devices. Micro bumps 142 may also be used to connect back sides of the chiplets to the module substrate 102.

Thin film processing sequences such as spin coating or lamination used for forming the package RDL 120 may be selected for ease of manufacturing, high throughput, and thickness requirements of the dielectric layers. It has been observed however that available materials for dielectric layers may be comparatively soft compared to materials such as silicon oxide and silicon nitride when deposited using alternative deposition techniques such as chemical vapor deposition (CVD) or physical vapor deposition (PVD). The dielectric layers 126 in accordance with embodiments may be formed of a material characterized by a Young's modulus of less than 20GPa. For example, the dielectric layers 126 may have an elastic modulus that is an order of magnitude less than that of the metal wiring layers and vias. For example, copper has a Young's modulus of approximately 130 GPa. Exemplary dielectric layer materials include polymers, such as polyamide, polyimide, etc.

In accordance with embodiments various metal wiring trace and via arrangements are described that may mitigate stress in the vias depending upon loading conditions. As shown in FIG. 1, the metal wiring traces 121, 125 and vias including top vias 132 (or via lines 135), intermediate vias 134, and lower vias 136 may be arranged with a staggered or cantilever routing arrangement 114, a U-turn routing arrangement 116, or symmetrical routing configuration 118. Such arrangements may reduce loading on the top vias 132 that contact the terminals 106 of the electronic components 104. In some embodiments, via lines 135 are used for contact with the terminals 106 of the electronic components 104. The via lines 135 in accordance with embodiments may be characterized by a line width and a longitudinal length that is greater than the line width and may be integrated with any metal wiring layer to mitigate stress.

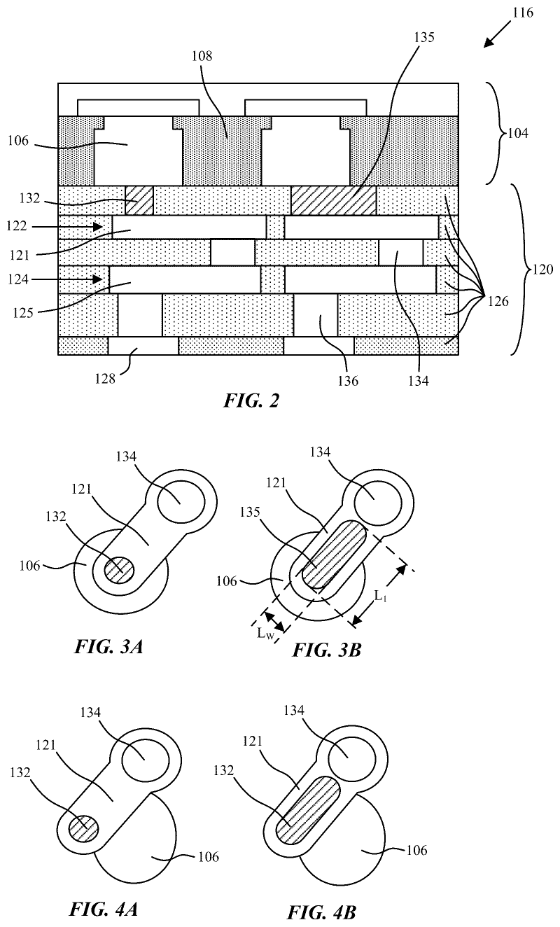

Referring now to FIG. 2 a schematic cross-sectional side view illustration is provided of package RDL 120 including a U-turn routing arrangement 116 and via line 135 connection in accordance with an embodiment. As shown, the U-turn routing arrangement 116 can reduce direct pressure applied to top via 132 from an underlying pressure source, such as through package terminal 128 and lower via 136. The U-turn routing configuration obtained by wiring traces 121, 125 and intermediate via 134 can mitigate this direct pressure. As shown, lower via 136 may be directly below the top via 132 or via line 135, while intermediate via 134 is offset a lateral distance (and not directly under). In this manner the intermediate via 134 and wiring traces 121, 125 form a U-turn routing configuration. In accordance with embodiments, a via line 135 connection can further mitigate stress. It is not required that the via line 135 be entirely underneath a footprint (area) of the terminal 106. For example, the via line 135 may be in direct contact with the terminal 106 and span across and be in direct contact with a bottommost passivation layer 108 of the electronic component 104.

Referring now to FIGS. 3A-3B and FIGS. 4A-4B various schematic bottom-top view illustrations are provided of a package RDL 120 top via 132 and wiring trace 121, and package RDL 120 via line 135 and wiring trace 121 that are either aligned or mis-aligned with an electronic component terminal 106 in accordance with embodiments. As shown, the via lines 135 in accordance with embodiments may be characterized by a line width (L_{w}) and a longitudinal line length (L₁) that is greater than the line width. Furthermore, the terminal 106 has a minimum width (W), or diameter, that is greater than the line width (L_{w}) of the via line 135, and diameter of top via 132. Referring now specifically to the mis-aligned configurations of FIGS. 4A-4B, in addition to structural integrity the via line 135 configuration can provide additional alignment tolerance. For example, the top via 132 misalignment in FIG. 4A may have insufficient metal-metal contact area between the top via 132 and terminal 106, while the misaligned via line 135 of FIG. 4B may have similar total metal-metal area as that of an aligned top via 132 of FIG. 3A.

Still referring to FIGS. 3A-4B, the immediately underling wiring trace 121 underneath via line 135 and top via 132 in accordance with embodiments may fully support the via line 135/top via 132 such that an entire shadow of the via line 135/top via 132 is directly above a portion of the wiring trace 121. Such an arrangement may be an example of fabrication technique where the wiring layer 122 is formed in the same plating operation as the via line 135/top via 132. Such an arrangement is not necessarily required in accordance with embodiments, particularly where via lines/vias are formed separately from adjacent wiring layers.

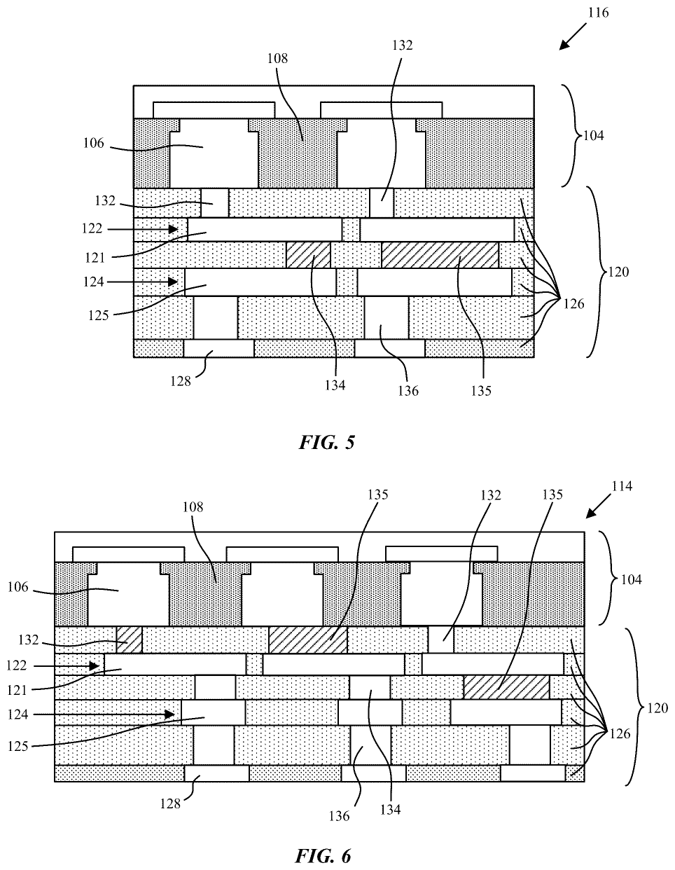

It is to be appreciated that while the particular configurations of FIGS. 3A-4B have been described with reference to FIG. 2, that such arrangements are not so limited and may be applied to other package RDL 120 constructions described herein. FIG. 5 illustrates one such embodiment where via line 135 connects adjacent metal wiring layers 122, 124, and may be fully supported by wiring trace 125.

Referring now to FIG. 6 a schematic cross-sectional side view illustration is provided of a package redistribution layer including a cantilever routing arrangement 114 and via line 135 connection in accordance with an embodiment. The configuration of FIG. 6 may be substantially similar to that illustrated and described with regard to FIGS. 2-5, with vias 134, 136 being aligned directly above one another and outside the shadow (area) of top via 132/via line 135. In this manner a cantilever configuration can be achieved to mitigate stress. Similar to FIGS. 2-5, via lines 135 can be used to connect a top metal wiring layer 122 to contact terminal 106 and/or to immediately vertically adjacent metal wiring layers 122, 124 in the package RDL 120.

Up until this point routing configurations have been described and illustrated in which separate wiring traces within the wiring layers are connected to separate terminals 106 of the electronic component 104. In some configurations the wiring traces within a common wiring layer may be connected, for example as a power or ground bar or plane.

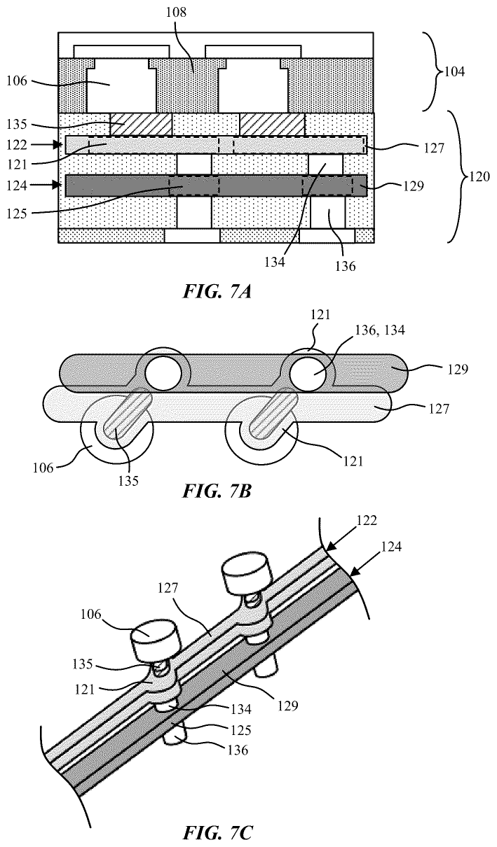

Referring now to FIGS. 7A-7C, schematic cross-sectional side view, bottom-top view, and perspective view illustrations are provided of package redistribution layer including a via line 135 connection and wiring bridges 127, 129 in accordance with an embodiment. It is to be appreciated that while the particular illustration of wiring bridges 127, 129 in FIGS. 7A-7C are shown with a cantilever configuration, that the wiring bridges 127, 129 can be implemented into any design described herein. As shown, wiring layer 122 may optionally include wiring traces 121 connected with wiring bridge 127 (e.g. optionally power bar or power plane), which may be electrically connected to both terminals 106 of the electronic component 104. The wiring bridge 127 and/or wiring bridge 129 may run in the same or different direction as the wiring traces 121, 125. In the particular embodiment illustrated the wiring bridge 127 runs at an angle to the wiring traces 121 to which it is joined, as well as via lines 135. It is to be appreciated that the via lines 135 can also or alternatively be integrated between wiring layers 122, 124.

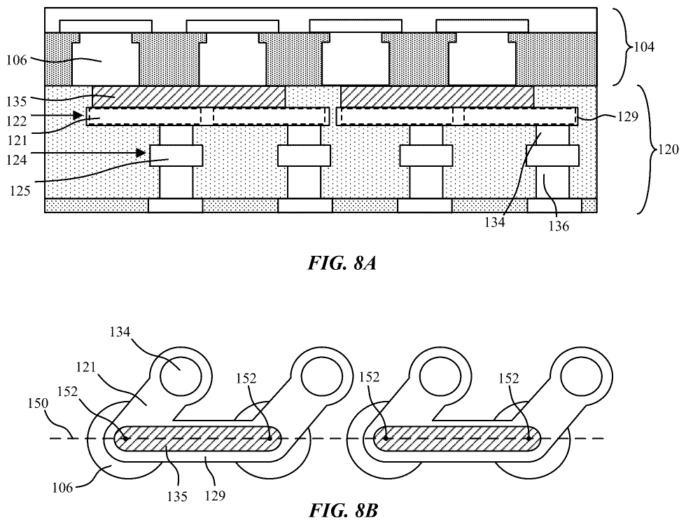

Multiple terminals 106 may also be connected with the via lines. Referring now to FIGS. 8A-8B, schematic cross-sectional side view and bottom-top view illustrations are provided of a package redistribution layer including a straight via line 135 bridging between two terminals 106 of an electronic component in accordance with an embodiment. The via lines 135 may be in direct contact with the multiple terminals 106. Depending upon fabrication technique the via lines 135 may or may not be fully supported by the uppermost wiring layer 122, such as with wiring traces 121 and/or wiring bridge 129. Wiring bridges 129 may optionally be power bars. In the particular embodiment illustrated in FIG. 8B the via line 135 spans in a direction of optional wiring bridge 129, while wiring traces 121 extend at an angle away from the wiring bridge 129. In an embodiment, the via line 135 is a straight line that spans directly underneath a center line 150 that extends between center points 152 of the terminals 106 to which it is connected.

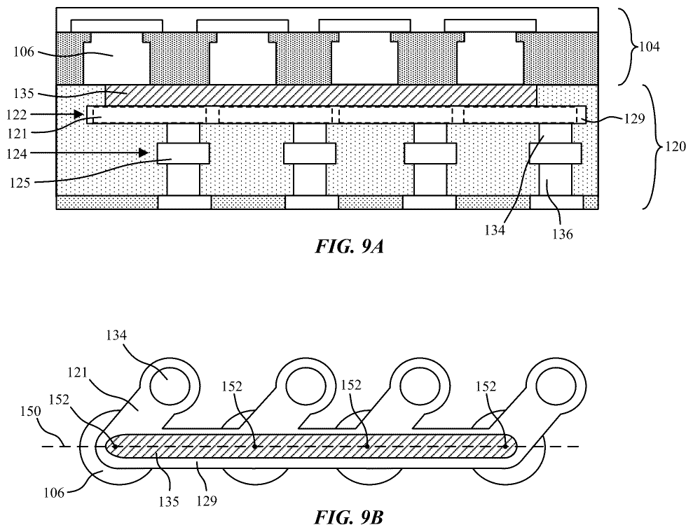

The via lines 135 may bridge to any number of terminals. FIGS. 9A-9B are schematic cross-sectional side view and bottom-top view illustrations of a package redistribution layer including a straight via line 135 bridging between multiple terminals 106 of an electronic component in accordance with an embodiment.

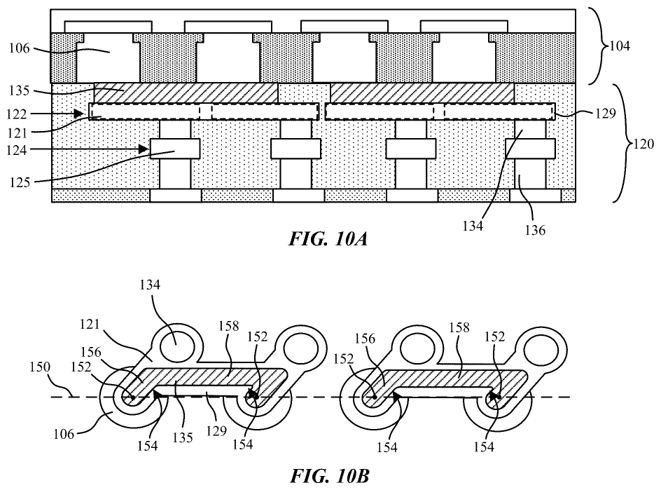

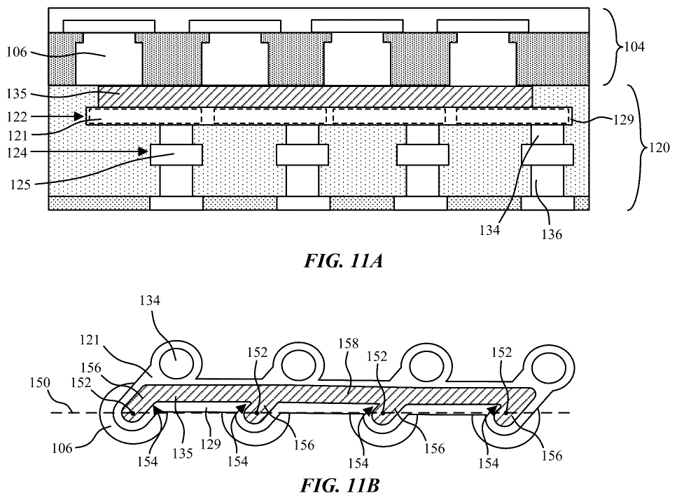

The bridging via lines 135 and optional wiring bridges 129 can assume a variety of patterns, including straight lines and may optionally include jogs. Referring now to FIGS. 10A-10B and FIGS. 11A-11B schematic cross-sectional side view and bottom-top view illustrations are provided of package redistribution layers including jogs 154 in a via line 135 that bridges between two (FIGS. 10A-10B) or more (FIGS. 11A-11B) terminals 106 of an electronic component in accordance with an embodiment. As shown, the via lines 135 may include a via line traces 156 connected to the terminals 106, and a via line bar 158 connecting the via line traces 156. The via line bar 158 may also be off-center such that the via line bar 158 does not span directly underneath a center line 150 that extends between center points 152 of the terminals 106.

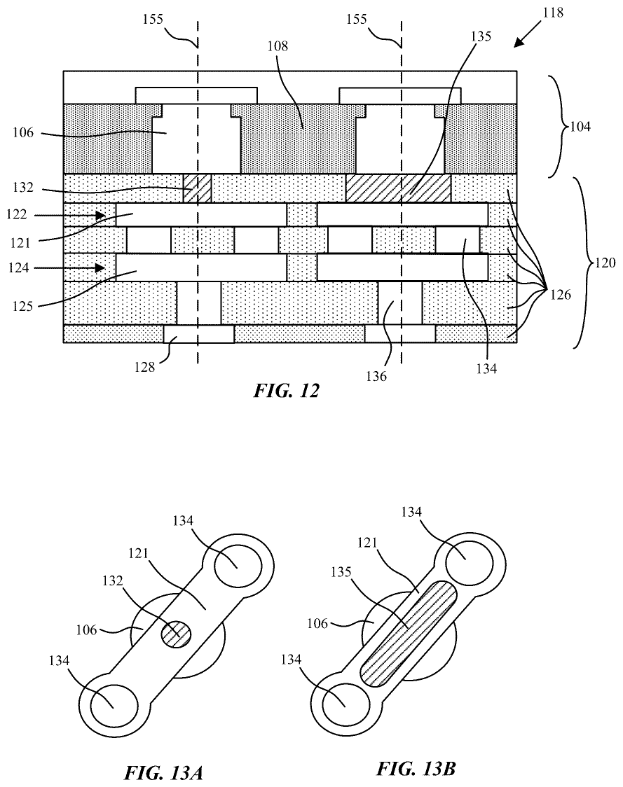

Stress can also be mitigated using a symmetrical routing configuration in accordance with embodiments. Referring now to FIG. 12 the configuration may be substantially similar to that illustrated and described with regard to FIGS. 2-5, with a pair of intermediate vias 134 connecting a lower wiring trace 125 and top wiring trace 121, with each of the intermediate vias 134 being equidistantly spaced in opposite lateral directions across the top wiring trace 121 and/or lower wiring trace 125. In a specific embodiment, such a symmetrical routing configuration 118 can mitigate direct transfer of pressure from lower via 136 to top via 132/via line 135.

The symmetrical routing configuration 118 in accordance with embodiments can be provided in combination with via line 135 connections. Referring now to FIGS. 13A-13B schematic bottom-top view illustrations of a package RDL 120 are provided including a top via 132 connection to terminal 106 and a via line 135 connection to terminal 106. The via line 135 may distribute stress over a larger area than the top via 132 connection, thereby preserving structural integrity and providing alignment tolerance.

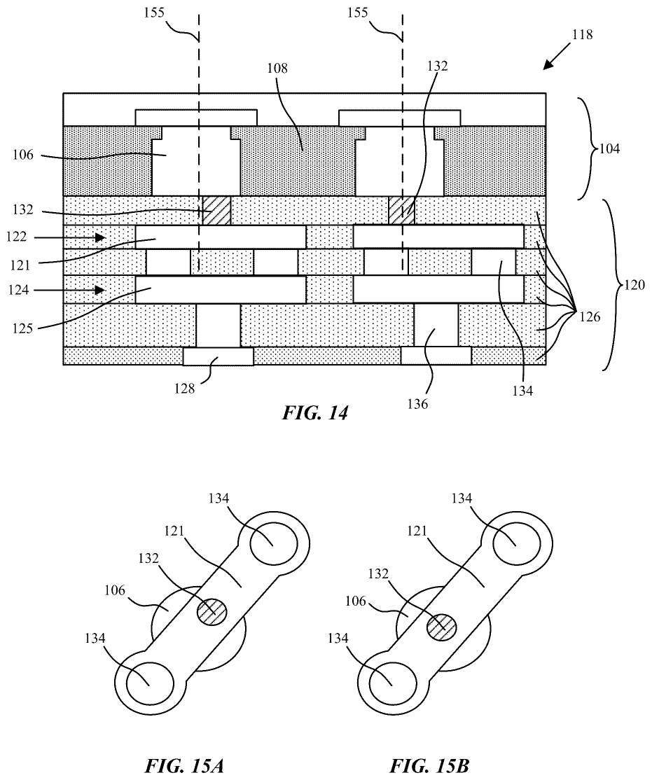

Referring now to FIG. 14 and FIGS. 15A-15B, schematic cross-sectional side view and bottom-top view illustrations are provided of a package RDL including offset (e.g. mis-aligned) symmetrical routing configurations in accordance with embodiments. As shown in FIG. 15A the entire symmetrical routing configuration 118, including the top via 122, may be offset from a vertical center 155 of the terminal 106 to which it is connected. For example, the top via 132 and lower via 136 of FIG. 14 are offset from the vertical center 155, whereas they are aligned in FIG. 12. Furthermore, the intermediate vias 134 are not equidistantly spaced apart from the vertical center 155 in FIG. 14, whereas they are equidistantly spaced apart from the vertical center in FIG. 12. Referring to FIG. 15B, the top via 122 alignment can be decoupled from the symmetrical routing configuration 118. In this embodiment the top dielectric layer can be selectively patterned (e.g. after measurement of reconstituted die location) to form the topmost via 132 so that it is aligned with the vertical center 155 of the terminal 106. The remainder of the symmetrical routing configuration 118 can then be formed using a pre-determined mask set, where alignment tolerance is compensated by the top wiring trace 121.

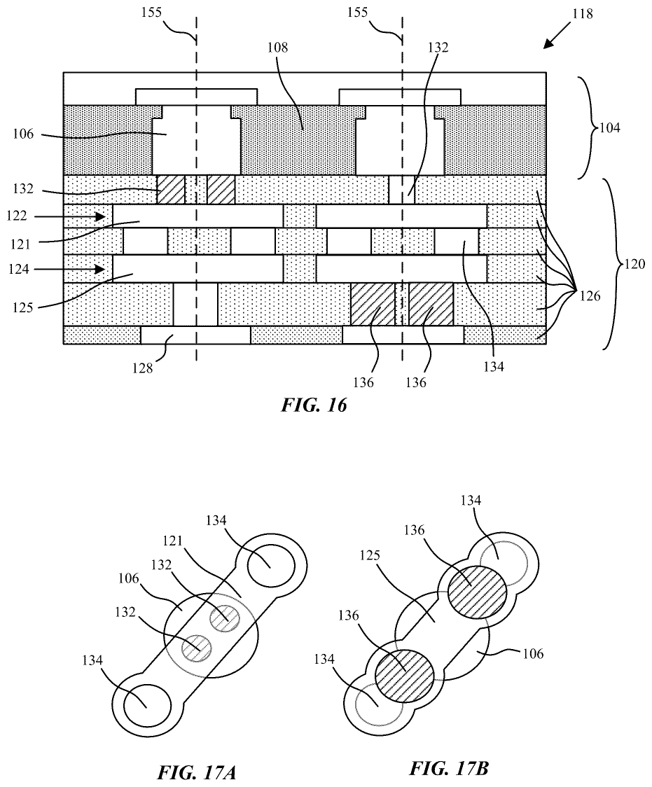

The symmetrical routing configurations 118 in accordance with embodiments may also have multiple via connections to/from any metal wiring layer, and combinations thereof. Referring to FIG. 16 and FIGS. 17A-17B, a schematic cross-sectional side view and bottom-top view illustrations are provided of a package RDL including symmetrical routing configurations with multiple via connections. As shown in FIG. 17A, the package RDL 120 can include multiple top via 132 connections. This configuration may also facilitate alignment tolerance of the package RDL 120 patterns so that the symmetrical routing configuration can be offset from the vertical center 155 of the corresponding terminal 106. The multiple top via 132 connections can also distribute stress in the top via layer. Stress can also be distributed using multiple lower via 136 connections to the same package terminal 128 as shown in FIG. 17B.

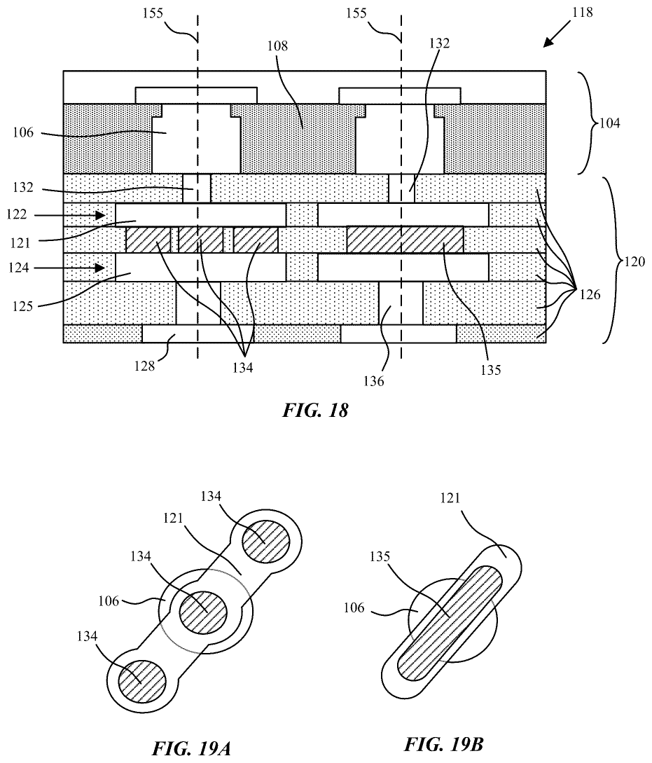

The symmetrical routing configuration 118 can also include multiple via connections and/or via lines 135 between metal wiring layers. Referring to FIG. 18 and FIGS. 19A-19B, a schematic cross-sectional side view and bottom-top view illustrations are provided of a package RDL including symmetrical routing configurations with multiple mid-level intermediate via 134 connections and a via line 135 connection. As shown in FIG. 19A, the package RDL 120 can include multiple mid-level intermediate via 134 connections to distributed stress. Stress can also be distributed using a mid-level via line 135 connection as shown in FIG. 19B.

In utilizing the various aspects of the embodiments, it would become apparent to one skilled in the art that combinations or variations of the above embodiments are possible for forming integrating a via line connection within a package RDL. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic package structure comprising:
an electronic component including a contact terminal;
a package redistribution layer (RDL) on the electronic component, wherein the package RDL comprises:
a plurality of wiring layers; and
a via line that connects a first wiring layer of the plurality of wiring layers to the contact terminal of the electronic component or to another wiring layer of the plurality of wiring layers.

2. The electronic package of claim 1, wherein the via line is characterized by a line width and a longitudinal line length that is greater than the line width.

3. The electronic package of claim 2, wherein the line via connection is fully supported by the first wiring layer such that an entire shadow of the line via connection is directly above a wiring trace of the first wiring layer.

4. The electronic package of claim 3, wherein the contact terminal has a minimum width that is greater than the line width of the via line.

5. The electronic package of claim 4, wherein the via line is in direct contact with the terminal and spans across and is in direct contact with a bottommost passivation layer of the electronic component.

6. The electronic package of claim 5, wherein the electronic component comprises a second contact terminal, and the via line is in direct contact with the second terminal.

7. The electronic package of claim 6, wherein the electronic component comprises a third contact terminal, and the via line is in direct contact with the third terminal.

8. The electronic package of claim 2, wherein the electronic component comprises a second contact terminal, and the via line is in direct contact with the second terminal.

9. The electronic package of claim 8, wherein the via line is a straight line, and the via line spans directly underneath a center line that extends between a first center point of the terminal and a second center point of the second terminal.

10. The electronic package of claim 8, wherein the via line includes one or more jogs.

11. The electronic package of claim 10, wherein the via line includes a first via line trace connected to the terminal, a second via line trace connected to the second terminal, and a via line bar connecting the first via line trace to the second via line trace.

12. The electronic package of claim 11, wherein the via line bar does not span directly underneath a center line that extends between a first center point of the terminal and a second center point of the second terminal.

13. The electronic package of claim 1, wherein the package RDL comprises a plurality of dielectric layers characterized by an elastic modulus below 20 GPa.

14. The electronic package of claim 13, wherein the plurality of dielectric layer is a plurality of polymer layers.

15. The electronic package of claim 14, wherein at least one of the plurality of wiring layers includes a wiring bridge that is electrically connected with the via line.

16. The electronic package of claim 15, wherein the wiring bridge is a power bar that is connected to multiple terminals of the electronic component.

17. The electronic package of claim 13, wherein the plurality of wiring layers includes a lower wiring layer, and the package RDL further comprises a pair of intermediate vias connecting a lower wiring trace of the lower wiring layer to a first wiring trace of the first wiring layer, and each intermediate via of the pair of intermediate vias is spaced in opposite lateral directions across the first wiring trace or the lower wiring trace to provide a symmetrical routing configuration.

18. An electronic system comprising:
a module substrate;
an electronic package mounted on the module substrate, wherein the electronic package comprises:
an electronic component including a contact terminal;
a package redistribution layer (RDL) on the electronic component, wherein the package RDL comprises:
a plurality of wiring layers; and
a via line that connects a first wiring layer of the plurality of wiring layers to the contact terminal of the electronic component, or to another wiring layer of the plurality of wiring layers.

19. The electronic system of claim 18, wherein the package RDL comprises a plurality of dielectric layers characterized by an elastic modulus below 20 GPa.

20. The electronic system of claim 19, wherein the package RDL comprises a plurality of package terminals, wherein the plurality of package terminals is bonded to the module substrate with a plurality of solder bumps.

21. The electronic system of claim 20, wherein the via line is characterized by a line width and a longitudinal line length that is greater than the line width.

22. An electronic package structure comprising:
an electronic component including a contact terminal;
a package redistribution layer (RDL) on the electronic component, wherein the package RDL comprises:
a plurality of wiring layers including a top wiring layer and a lower wiring layer; and
a pair of intermediate vias connecting a lower wiring trace of the lower wiring layer to a top wiring trace of the top wiring layer;
a top via that connects the top wiring trace to the contact terminal of the electronic component; and
a lower via connected beneath the lower wiring trace;
wherein each intermediate via of the pair of intermediate vias is spaced in opposite lateral directions across the top wiring trace or the lower wiring trace to provide a symmetrical routing configuration.

23. The electronic package of claim 22, wherein the top via is aligned with a vertical center of the terminal.

24. The electronic package of claim 22, wherein the top via is misaligned with a vertical center of the terminal.

25. The electronic package of claim 22, further comprising a second top via that connects the top wiring trace to the contact terminal of the electronic component.
